(19) United States
(12) Patent Application Publication
(10) Pub. No.: US 2022/0301854 A1
(43) Pub. Date: Sep. 22, 2022

(54) METHOD OF PROCESSING SUBSTRATE, METHOD OF MANUFACTURING SEMICONDUCTOR DEVICE, SUBSTRATE PROCESSING SYSTEM, AND RECORDING MEDIUM

(71) Applicant: Kokusai Electric Corporation, Tokyo (JP)

(72) Inventors: Hideki HORITA, Toyama-shi (JP); Masahiro TAKAHASHI, Toyama-shi (JP)

(73) Assignee: Kokusai Electric Corporation, Tokyo (JP)

(21) Appl. No.: 17/675,633

(22) Filed: Feb. 18, 2022

(30) Foreign Application Priority Data
Mar. 22, 2021 (JP) 2021-047313

(51) Int. Cl. H01L 21/02; C23C 16/455; C23C 16/52

(52) U.S. Cl. CPC H01L 21/0228; C23C 16/45553; C23C 16/45563; C23C 16/52; C23C 16/402

(57) ABSTRACT

There is provided a technique that includes: (a) forming a first film in an amorphous state on the substrate by supplying a first process gas to the substrate; (b) forming a second film in an amorphous state, which has a crystallization temperature lower than a crystallization temperature of the first film, on the first film by supplying a second process gas to the substrate; (c) crystallizing the first film and the second film formed on the substrate by heating the first film and the second film; and (d) removing at least the second film by exposing a surface of the substrate to an etching agent after crystallizing the first film and the second film.

### CROSS-REFERENCE TO RELATED APPLICATION

This application is based upon and claims the benefit of priority from Japanese Patent Application No. 2021-047313, filed on Mar. 22, 2021, the entire contents of which are incorporated herein by reference.

### TECHNICAL FIELD

The present disclosure relates to a method of processing a substrate, a method of manufacturing a semiconductor device, a substrate processing system, and a recording medium.

### BACKGROUND

As a process of manufacturing a semiconductor device, a process of forming a film on a substrate may be often carried out.

### SUMMARY

Some embodiments of the present disclosure provide a technique capable of forming a high quality film on a substrate.

According to one embodiment of the present disclosure, there is provided a technique that includes: (a) forming a first film in an amorphous state on the substrate by supplying a first process gas to the substrate; (b) forming a second film in an amorphous state, which has a crystallization temperature lower than a crystallization temperature of the first film, on the first film by supplying a second process gas to the substrate; (c) crystallizing the first film and the second film formed on the substrate by heating the first film and the second film; and (d) removing at least the second film by exposing a surface of the substrate to an etching agent after crystallizing the first film and the second film.

### BRIEF DESCRIPTION OF DRAWINGS

The accompanying drawings, which are incorporated in and constitute a part of the specification, illustrate embodiments of the present disclosure.

FIG. 1 is a schematic configuration view of a vertical process furnace of a substrate processing system suitably used in embodiments of the present disclosure, in which a portion of the process furnace is shown in a vertical cross section.

FIG. 2 is a schematic configuration view of the vertical process furnace of the substrate processing system suitably used in embodiments of the present disclosure, in which a portion of the process furnace is shown in a cross section taken along line A-A in FIG. 1.

FIG. 3 is a schematic configuration diagram of a controller of the substrate processing system suitably used in embodiments of the present disclosure, in which a control system of the controller is shown in a block diagram.

FIG. 4A is a partially-enlarged cross-sectional view of a wafer surface before a film-forming process is performed in a substrate processing sequence according to a first embodiment of the present disclosure.

FIG. 4B is a partially-enlarged cross-sectional view of the wafer surface after seed layer formation in the substrate processing sequence according to the first embodiment of the present disclosure.

FIG. 4C is a partially-enlarged cross-sectional view of the wafer surface after first film formation in the substrate processing sequence according to the first embodiment of the present disclosure.

FIG. 4D is a partially-enlarged cross-sectional view of the wafer surface after second film formation in the substrate processing sequence according to the first embodiment of the present disclosure.

FIG. 4E is a partially-enlarged cross-sectional view of the wafer surface after crystallization in the substrate processing sequence according to the first embodiment of the present disclosure.

FIG. 4F is a partially-enlarged cross-sectional view of the wafer surface after modification in the substrate processing sequence according to the first embodiment of the present disclosure.

FIG. 4G is a partially-enlarged cross-sectional view of the wafer surface after etching in the substrate processing sequence according to the first embodiment of the present disclosure.

FIG. 5A is a partially-enlarged cross-sectional view of a wafer surface before a film-forming process is performed in a substrate processing sequence according to a modification of the first embodiment of the present disclosure.

FIG. 5B is a partially-enlarged cross-sectional view of the wafer surface after seed layer formation in the substrate processing sequence according to the modification of the first embodiment of the present disclosure.

FIG. 5C is a partially-enlarged cross-sectional view of the wafer surface after first film formation in the substrate processing sequence according to the modification of the first embodiment of the present disclosure.

FIG. 5D is a partially-enlarged cross-sectional view of the wafer surface after second film formation in the substrate processing sequence according to the modification of the first embodiment of the present disclosure.

FIG. 5E is a partially-enlarged cross-sectional view of the wafer surface after crystallization in the substrate processing sequence according to the modification of the first embodiment of the present disclosure.

FIG. 5F is a partially-enlarged cross-sectional view of the wafer surface after etching in the substrate processing sequence according to the modification of the first embodiment of the present disclosure.

FIG. 6A is a partially-enlarged cross-sectional view of a wafer surface before a film-forming process is performed in a substrate processing sequence according to a second embodiment of the present disclosure.

FIG. 6B is a partially-enlarged cross-sectional view of the wafer surface after seed layer formation in the substrate processing sequence according to the second embodiment of the present disclosure.

FIG. 6C is a partially-enlarged cross-sectional view of the wafer surface after first film formation in the substrate processing sequence according to the second embodiment of the present disclosure.

FIG. 6D is a partially-enlarged cross-sectional view of the wafer surface after second film formation in the substrate processing sequence according to the second embodiment of the present disclosure.

FIG. 6E is a partially-enlarged cross-sectional view of the wafer surface after crystallization in the substrate processing sequence according to the second embodiment of the present disclosure.

FIG. 6F is a partially-enlarged cross-sectional view of the wafer surface after modification in the substrate processing sequence according to the second embodiment of the present disclosure.

FIG. 6G is a partially-enlarged cross-sectional view of the wafer surface after etching in the substrate processing sequence according to the second embodiment of the present disclosure.

FIG. 7A is a partially-enlarged cross-sectional view of a wafer surface before a film-forming process is performed in a substrate processing sequence according to a modification of the second embodiment of the present disclosure.

FIG. 7B is a partially-enlarged cross-sectional view of the wafer surface after seed layer formation in the substrate processing sequence according to the modification of the second embodiment of the present disclosure.

FIG. 7C is a partially-enlarged cross-sectional view of the wafer surface after first film formation in the substrate processing sequence according to the modification of the second embodiment of the present disclosure.

FIG. 7D is a partially-enlarged cross-sectional view of the wafer surface after second film formation in the substrate processing sequence according to the modification of the second embodiment of the present disclosure.

FIG. 7E is a partially-enlarged cross-sectional view of the wafer surface after crystallization in the substrate processing sequence according to the modification of the second embodiment of the present disclosure.

FIG. 7F is a partially-enlarged cross-sectional view of the wafer surface after etching in the substrate processing sequence according to the modification of the second embodiment of the present disclosure.

FIG. 8A is a schematic diagram showing an aspect of a substrate processing system when a batch-type substrate processing apparatus is used.

FIG. 8B is a schematic diagram showing another aspect of the substrate processing system when the batch-type substrate processing apparatus is used.

FIG. 9 is a schematic diagram showing an aspect of a substrate processing system when a single-wafer cluster-type substrate processing apparatus is used.

FIG. 10 is a diagram showing evaluation results in Example 1 and Comparative Example 1.

FIG. 11 is a diagram showing evaluation results in Example 2 and Comparative Example 2.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment of the Present Disclosure

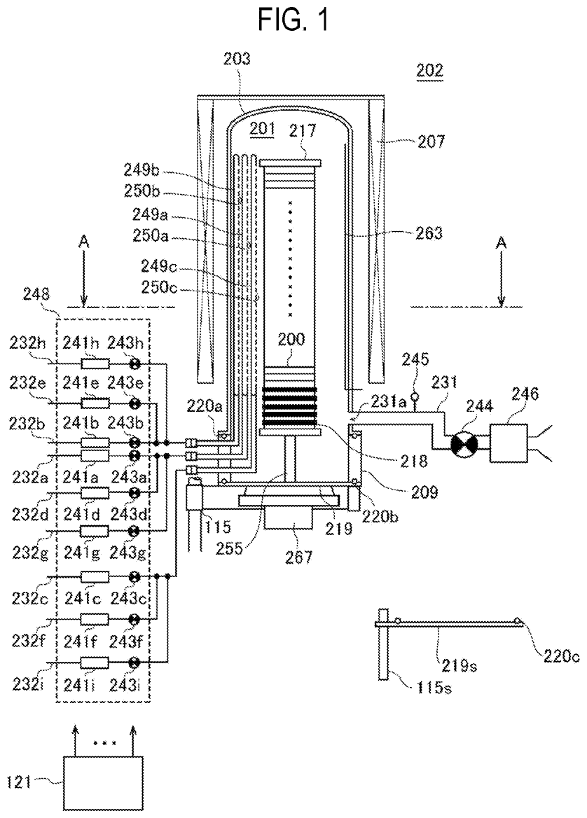

A first embodiment of the present disclosure will be now described mainly with reference to FIGS. 1 to 3 and 4A to 4G. The drawings used in the following description are all schematic, and the dimensional relationship, ratios, and the like of various elements shown in figures do not always match the actual ones. Further, the dimensional relationship, ratios, and the like of various elements between plural figures do not always match each other.

### (1) Configuration of Substrate Processing Apparatus

As shown in FIG. 1, a process furnace 202 includes a heater 207 as a temperature adjustor (a heating part). The heater 207 has a cylindrical shape and is supported by a support plate so as to be vertically installed. The heater 207 also functions as an activation mechanism (an excitation part) configured to thermally activate (excite) a gas.

A reaction tube 203 is disposed inside the heater 207 to be concentric with the heater 207. The reaction tube 203 is made of, for example, a heat resistant material such as quartz (SiO₂) or silicon carbide (SiC), and has a cylindrical shape with its upper end closed and its lower end opened. A manifold 209 is disposed to be concentric with the reaction tube 203 under the reaction tube 203. The manifold 209 is made of, for example, a metal material such as stainless steel (SUS), and has a cylindrical shape with both of its upper and lower ends opened. The upper end portion of the manifold 209 engages with the lower end portion of the reaction tube 203 so as to support the reaction tube 203. An O-ring 220a serving as a seal member is installed between the manifold 209 and the reaction tube 203. Similar to the heater 207, the reaction tube 203 is vertically installed. A process container (reaction container) is mainly constituted by the reaction tube 203 and the manifold 209. A process chamber 201 is formed in a hollow cylindrical portion of the process container. The process chamber 201 is configured to accommodate a plurality of wafers 200 as substrates. Processing on the wafers 200 is performed in the process chamber 201.

Nozzles 249a to 249c as first to third supplier are installed in the process chamber 201 so as to penetrate through a sidewall of the manifold 209. The nozzles 249a to 249c are also referred to as first to third nozzles, respectively. The nozzles 249a to 249c are made of, for example, a heat resistant material such as quartz or SiC. Gas supply pipes 232a to 232c are connected to the nozzles 249a to 249c, respectively. The nozzles 249a to 249c are different nozzles, and each of the nozzles 249a and 249c is installed adjacent to the nozzle 249b.

Mass flow controllers (MFCs) 241a to 241c, which are flow rate controllers (flow rate control parts), and valves 243a to 243c, which are opening/closing valves, are installed in the gas supply pipes 232a to 232c, respectively, sequentially from the upstream side of a gas flow. Gas supply pipes 232d and 232g are connected to the gas supply pipe 232a at the downstream side of the valve 243a. Gas supply pipes 232e and 232h are connected to the gas supply pipe 232b at the downstream side of the valve 243b. Gas supply pipes 232f and 232i are connected to the gas supply pipe 232c at the downstream side of the valve 243c. MFCs 241d to 241i and valves 243d to 243i are installed in the gas supply pipes 232d to 232i, respectively, sequentially from the upstream side of a gas flow. The gas supply pipes 232a to 232i are made of, for example, a metal material such as SUS.

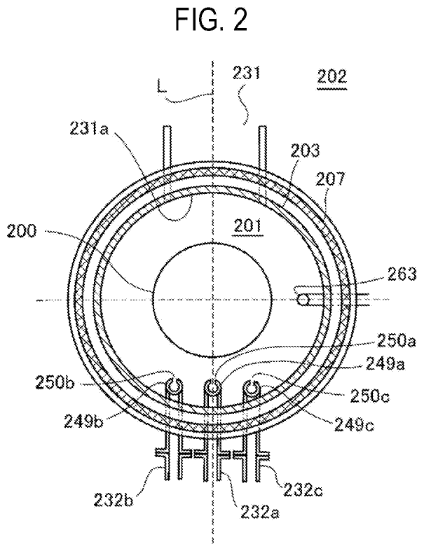

As shown in FIG. 2, each of the nozzles 249a to 249c is disposed in an annular space in a plane view between an inner wall of the reaction tube 203 and the wafers 200 so as to extend upward from a lower portion of the inner wall of the reaction tube 203 to an upper portion thereof, that is, along an arrangement direction of the wafers 200. Specifically, each of the nozzles 249a to 249c is installed in a region horizontally surrounding a wafer arrangement region in which the wafers 200 are arranged at a lateral side of the wafer arrangement region, along the wafer arrangement region. In a plane view, the nozzle 249a is disposed so as to face an exhaust port 231a to be described later in a straight line with the centers of the wafers 200 loaded into the process chamber 201, which are interposed therebetween. The nozzles 249b and 249c are arranged so as to sandwich a straight line L passing through the nozzle 249a and the center of the exhaust port 231a from both sides along the inner wall of the reaction tube 203 (the outer peripheral portion of the wafers 200). The straight line L is also a straight line passing through the nozzle 249a and the centers of the wafers 200. That is, it can be said that the nozzle 249c is installed on the side opposite to the nozzle 249b with the straight line L interposed therebetween. The nozzles 249b and 249c are arranged in line symmetry with the straight line L as the axis of symmetry. Gas supply holes 250a to 250c for supplying a gas are formed on the side surfaces of the nozzles 249a to 249c, respectively. Each of the gas supply holes 250a to 250c is opened so as to oppose (face) the exhaust port 231a in a plane view, which enables a gas to be supplied toward the wafers 200. A plurality of gas supply holes 250a to 250c are formed from the lower portion of the reaction tube 203 to the upper portion thereof.

A precursor gas containing a main element (predetermined element) constituting a film to be formed on the wafers 200 is supplied from the gas supply pipe 232a into the process chamber 201 via the MFC 241a, the valve 243a, and the nozzle 249a.

A seed gas is supplied from the gas supply pipe 232b into the process chamber 201 via the MFC 241b, the valve 243b, and the nozzle 249b.

A dopant gas containing a dopant (impurity) added to a film to be formed on the wafers 200 is supplied from the gas supply pipe 232c into the process chamber 201 via the MFC 241c, the valve 243c, and the nozzle 249c.

A reducing gas is supplied from the gas supply pipe 232d into the process chamber 201 via the MFC 241d, the valve 243d, the gas supply pipe 232a, and the nozzle 249a.

An etching agent is supplied from the gas supply pipe 232e into the process chamber 201 via the MFC 241e, the valve 243e, the gas supply pipe 232b, and the nozzle 249b.

A modifying gas is supplied from the gas supply pipe 232f into the process chamber 201 via the MFC 241f, the valve 243f, the gas supply pipe 232c, and the nozzle 249c.

An inert gas is supplied from the gas supply pipes 232g to 232i into the process chamber 201 via the MFCs 241g to 241i, the valves 243g to 243i, the gas supply pipes 232a to 232c, and the nozzles 249a to 249c, respectively. The inert gas acts as a purge gas, a carrier gas, a dilution gas, or the like.

A precursor gas supply system mainly includes the gas supply pipe 232a, the MFC 241a, and the valve 243a. A seed gas supply system mainly includes the gas supply pipe 232b, the MFC 241b, and the valve 243b. A dopant gas supply system mainly includes the gas supply pipe 232c, the MFC 241c, and the valve 243c. A reducing gas supply system mainly includes the gas supply pipe 232d, the MFC 241d, and the valve 243d. An etching agent supply system (etching agent exposure system) mainly includes the gas supply pipe 232e, the MFC 241e, and the valve 243e. A modifying gas supply system mainly includes the gas supply pipe 232f, the MFC 241f, and the valve 243f An inert gas supply system mainly includes the gas supply pipes 232g to 232i, the MFCs 241g to 241i, and the valves 243g to 243i.

At least one of the precursor gas, the seed gas, the dopant gas, the reducing gas, and the modifying gas is also referred to as a process gas (first process gas, second process gas), and at least one of the precursor gas supply system, the seed gas supply system, and the dopant gas supply system is also referred to as a process gas supply system (first process gas supply system, second process gas supply system).

One or all of the above-described various gas supply systems may be configured as an integrated-type gas supply system 248 in which the valves 243a to 243i, the MFCs 241a to 241i, and so on are integrated. The integrated-type gas supply system 248 is connected to each of the gas supply pipes 232a to 232i. In addition, the integrated-type gas supply system 248 is configured such that operations of supplying various gases into the gas supply pipes 232a to 232i (that is, the opening/closing operation of the valves 243a to 243i, the flow rate adjustment operation by the MFCs 241a to 241i, and the like) are controlled by a controller 121 which will be described later. The integrated-type gas supply system 248 is configured as an integral type or detachable-type integrated unit, and may be attached to and detached from the gas supply pipes 232a to 232i and the like on an integrated unit basis, so that the maintenance, replacement, extension, etc. of the integrated-type gas supply system 248 can be performed on an integrated unit basis.

The exhaust port 231a for exhausting an internal atmosphere of the process chamber 201 is installed below the sidewall of the reaction tube 203. As shown in FIG. 2, in a plane view, the exhaust port 231a is installed at a position opposing (facing) the nozzles 249a to 249c (the gas supply holes 250a to 250c) with the wafers 200 interposed therebetween. The exhaust port 231a may be installed from a lower portion of the sidewall of the reaction tube 203 to an upper portion thereof, that is, along the wafer arrangement region. An exhaust pipe 231 is connected to the exhaust port 231a. The exhaust pipe 231 is made of, for example, a metal material such as SUS. A vacuum exhaust device, for example, a vacuum pump 246, is connected to the exhaust pipe 231 via a pressure sensor 245, which is a pressure detector (pressure detecting part) for detecting the internal pressure of the process chamber 201, and an auto pressure controller (APC) valve 244, which is a pressure regulator (pressure adjustment part). The APC valve 244 is configured to perform or stop a vacuum exhausting operation in the process chamber 201 by opening/closing the valve while the vacuum pump 246 is actuated, and is also configured to adjust the internal pressure of the process chamber 201 by adjusting an opening degree of the valve based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219, which serves as a furnace opening cover configured to hermetically seal a lower end opening of the manifold 209, is installed under the manifold 209. The seal cap 219 is made of, for example, a metal material such as SUS, and is formed in a disc shape. An O-ring 220b, which is a seal member making contact with the lower end of the manifold 209, is installed on an upper surface of the seal cap 219. A rotation mechanism 267 configured to rotate a boat 217, which will be described later, is installed under the seal cap 219. A rotary shaft 255 of the rotation mechanism 267 is made of, for example, a metal material such as SUS, and is connected to the boat 217 through the seal cap 219. The rotation mechanism 267 is configured to rotate the wafers 200 by rotating the boat 217. The seal cap 219 is configured to be vertically moved up and down by a boat elevator 115 which is an elevating mechanism installed outside the reaction tube 203. The boat elevator 115 is configured as a transfer device (transfer mechanism) which loads/unloads (transfers) the wafers 200 into/out of the process chamber 201 by moving the seal cap 219 up and down.

A shutter 219s, which serves as a furnace opening cover configured to hermetically seal a lower end opening of the manifold 209 in a state where the seal cap 219 is lowered and the boat 217 is unloaded from the process chamber 201, is installed under the manifold 209. The shutter 219s is made of, for example, a metal material such as SUS, and is formed in a disc shape. An O-ring 220c, which is a seal member making contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. As such, the boat 217 is configured to arrange the wafers 200 to be spaced apart from each other. The boat 217 is made of, for example, a heat resistant material such as quartz or SiC. Heat insulating plates 218 made of, for example, a heat resistant material such as quartz or SiC are installed below the boat 217 in multiple stages.

A temperature sensor 263 serving as a temperature detector is installed in the reaction tube 203. Based on temperature information detected by the temperature sensor 263, a state of supplying electric power to the heater 207 is adjusted such that an interior of the process chamber 201 has a desired temperature distribution. The temperature sensor 263 is installed along the inner wall of the reaction tube 203.

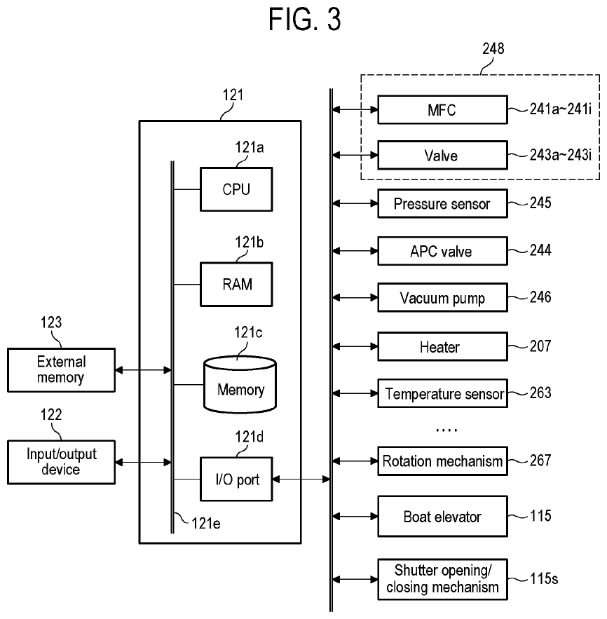

As shown in FIG. 3, a controller 121, which is a control part (control means), may be configured as a computer including a central processing unit (CPU) 121a, a random access memory (RAM) 121b, a memory 121c, and an I/O port 121d. The RAM 121b, the memory 121c, and the I/O port 121d are configured to exchange data with the CPU 121a via an internal bus 121e. An input/output device 122 formed of, e.g., a touch panel or the like, is connected to the controller 121. Further, an external memory 123 can be connected to the controller 121.

The memory 121c is configured by, for example, a flash memory, a hard disk drive (HDD), or the like. A control program for controlling operations of a substrate processing apparatus, a process recipe in which sequences and conditions of substrate processing to be described later are written, etc. are readably stored in the memory 121c. The process recipe functions as a program for causing the controller 121 to execute each sequence in the substrate processing, which will be described later, to obtain an expected result. Hereinafter, the process recipe and the control program may be generally and simply referred to as a “program.” Furthermore, the process recipe may be simply referred to as a “recipe.” When the term “program” is used herein, it may indicate a case of including the recipe only, a case of including the control program only, or a case of including both the recipe and the control program. The RAM 121b is configured as a memory area (work area) in which a program or data read by the CPU 121a is temporarily stored.

The I/O port 121d is connected to the MFCs 241a to 241i, the valves 243a to 243i, the pressure sensor 245, the APC valve 244, the vacuum pump 246, the temperature sensor 263, the heater 207, the rotation mechanism 267, the boat elevator 115, the shutter opening/closing mechanism 115s, and so on.

The CPU 121a is configured to read and execute the control program from the memory 121c. The CPU 121a is also configured to read the recipe from the memory 121c according to an input of an operation command from the input/output device 122. In addition, the CPU 121a is configured to control the flow rate adjusting operation of various kinds of gases by the MFCs 241a to 241i, the opening/closing operation of the valves 243a to 243i, the opening/closing operation of the APC valve 244, the pressure adjusting operation performed by the APC valve 244 based on the pressure sensor 245, the actuating and stopping operation of the vacuum pump 246, the temperature adjusting operation performed by the heater 207 based on the temperature sensor 263, the operation of rotating the boat 217 with the rotation mechanism 267 and adjusting the rotation speed of the boat 217, the operation of moving the boat 217 up and down by the boat elevator 115, the opening/closing operation of the shutter 219s by the shutter opening/closing mechanism 115s, and so on, according to contents of the read recipe.

The controller 121 may be configured by installing, on the computer, the aforementioned program stored in the external memory 123. Examples of the external memory 123 may include a magnetic disk such as a HDD, an optical disc such as a CD, a magneto-optical disc such as a MO, a semiconductor memory such as a USB memory and SSD, and the like. The memory 121c or the external memory 123 is configured as a non-transitory computer-readable recording medium. Hereinafter, the memory 121c and the external memory 123 may be generally and simply referred to as a “recording medium.” When the term “recording medium” is used herein, it may indicate a case of including the memory 121c only, a case of including the external memory 123 only, or a case of including both the memory 121c and the external memory 123. Furthermore, the program may be provided to the computer using communication means such as the Internet or a dedicated line, instead of using the external memory 123.

A substrate processing system according to the present embodiment can be configured by the above-described batch-type substrate processing apparatus.

### (2) Substrate Processing Process

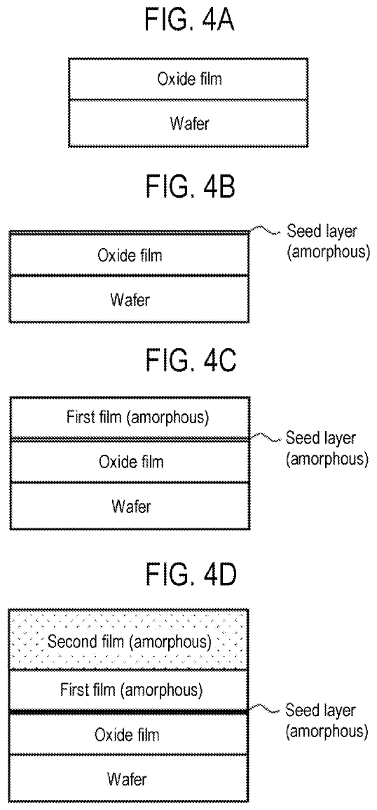

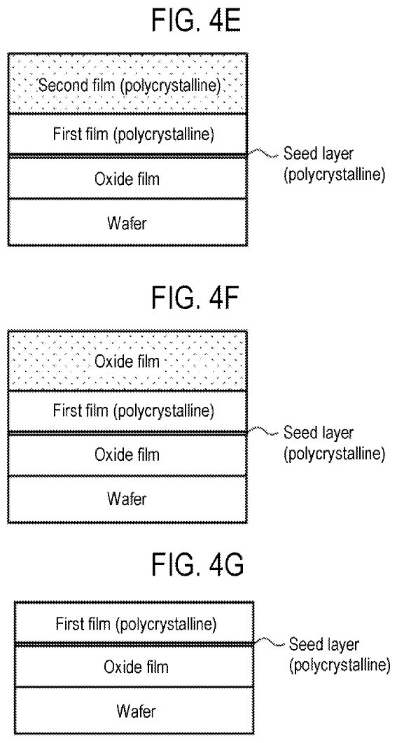

As a process of manufacturing a semiconductor device using the above-described substrate processing apparatus, a processing sequence example of forming a film on a wafer 200 as a substrate will be described mainly with reference to FIGS. 4A to 4G. In the following descriptions, the operations of the respective parts constituting the substrate processing apparatus are controlled by the controller 121.

A processing sequence according to the first embodiment includes:
(a) step A of forming a first film in an amorphous state on a wafer 200 by supplying a first process gas to the wafer 200;
(b) step B of forming a second film in an amorphous state, which has a crystallization temperature lower than a crystallization temperature of the first film, on the first film by supplying a second process gas to the wafer 200;
(c) step C of crystallizing the first film and the second film by heating the first film and the second film formed on the wafer 200; and
(d) step D of removing at least the second film by exposing a surface of the wafer 200 to an etching agent after crystallizing the first film and the second film.

In this case, the first film can be a film not doped with a dopant, and the second film can be a film doped with a dopant. As the dopant, at least one selected from the group of phosphorus (P), boron (B), and arsenic (As) can be used.

In step A, a seed layer may be formed before the first film is formed. In this case, the seed layer is formed on the surface of the wafer 200, and the first film is formed on the seed layer.

In step A, when a first silicon film not doped with a dopant is formed as the first film, a precursor gas such as a silane-based gas can be used as the first process gas.

In step B, when a second silicon film doped with a dopant is formed as the second film, a precursor gas, such as a silane-based gas, and a dopant gas can be used as the second process gas.

When some of dopants in the second film are diffused into the first film in step C, a portion of the first film into which the dopants in the second film are diffused may be removed in step D. In this case, in step D, the surface of the first film that does not contain the dopants may be exposed.

The processing sequence according to the first embodiment may further include: (e) step E of modifying at least one portion, where the dopant is present, in at least one selected from the group of the first film and the second film after performing step C and before performing step D. In this case, in step E, the portion of the first film and the second film in which the dopants are present may be oxidized. This makes it possible to easily remove (easily etch by the etching agent) in step D the portion of the first film and the second film in which the dopants are present after performing step C.

In the present disclosure, for the sake of convenience, the above-described processing sequence may be denoted as follows. The same denotation may be used in other embodiments and modifications to be described later.

Seed layer formation→First film formation→Second film formation→Crystallization Modification→Etching

When the term “wafer” is used in the present disclosure, it may refer to “a wafer itself” or “a wafer and a stacked body of certain layers or films formed on a surface of the wafer.” When the phrase “a surface of a wafer” is used in the present disclosure, it may refer to “a surface of a wafer itself” or “a surface of a certain layer formed on a wafer.” When the expression “a certain layer is formed on a wafer” is used in the present disclosure, it may mean that “a certain layer is formed directly on a surface of a wafer itself” or that “a certain layer is formed on a layer formed on a wafer.” When the term “substrate” is used in the present disclosure, it may be synonymous with the term “wafer.”

### (Wafer Charging and Boat Loading)

After the boat 217 is charged with a plurality of wafers 200 (wafer charging), the shutter 219s is moved by the shutter opening/closing mechanism 115s to open the lower end opening of the manifold 209 (shutter opening). After that, as shown in FIG. 1, the boat 217 charged with the plurality of wafers 200 is lifted up by the boat elevator 115 to be loaded into the process chamber 201 (boat loading). In this state, the seal cap 219 seals the lower end of the manifold 209 through the O-ring 220b. As shown in FIG. 4A, an oxide film, for example, a silicon oxide film (SiO film), is previously formed on the surface of the wafer 200.

### (Pressure Adjustment and Temperature Adjustment)

After the boat loading is completed, the interior of the process chamber 201, that is, a space where the wafers 200 are placed, is vacuum-exhausted (decompression-exhausted) by the vacuum pump 246 to reach a desired pressure (degree of vacuum). At this time, the internal pressure of the process chamber 201 is measured by the pressure sensor 245, and the APC valve 244 is feedback-controlled based on the measured pressure information (pressure adjustment). Further, the wafers 200 in the process chamber 201 are heated by the heater 207 so as to have a desired temperature. At this time, the state of supplying electric power to the heater 207 is feedback-controlled based on the temperature information detected by the temperature sensor 263 so that the interior of the process chamber 201 has a desired temperature distribution (temperature adjustment). Further, the rotation of the wafers 200 by the rotation mechanism 267 is started. The exhaust of the interior of the process chamber 201 and the heating and rotation of the wafers 200 are continuously performed at least until the processing on the wafers 200 is completed.

### (Step A)

After that, step A is performed. In this step, the following seed layer formation and first film formation are performed in order.

### [Seed Layer Formation]

In seed layer formation, the following steps S1 and S2 are sequentially executed.

### [Step S1]

In step S1, a seed gas is supplied to the wafer 200 in the process chamber 201, that is, the surface of the oxide film formed on the wafer 200.

Specifically, the valve 243b is opened to allow the seed gas to flow into the gas supply pipe 232b. The flow rate of the seed gas is adjusted by the MFC 241b, and the seed gas is supplied into the process chamber 201 via the nozzle 249b and is exhausted through the exhaust pipe 231. In this operation, the seed gas is supplied to the wafer 200 (seed gas supply). At this time, the valves 243g to 243i may be opened to allow an inert gas to be supplied into the process chamber 201 via the nozzles 249a to 249c, respectively.

An example of the process condition in the seed gas supply is described as follows.
Seed gas supply flow rate: 0.1 to 1 slm
Seed gas supply time: 0.5 to 2 minutes
Inert gas supply flow rate (for each gas supply pipe): 0 to 20 slm
Processing temperature: 350 to 450 degrees C., specifically 350 to 400 degrees C.
Processing pressure: 277 to 1,200 Pa, specifically 667 to 1,200 Pa

In the present disclosure, the notation of a numerical range such as “277 to 1,200 Pa” means that the lower limit value and the upper limit value are included in the range. For example, “277 to 1,200 Pa” means “equal to or more than 277 Pa and equal to or less than 1,200 Pa.” The same applies to other numerical ranges. Further, in the present disclosure, the processing temperature means the temperature of the wafer 200 or the internal temperature of the process chamber 201, and the processing pressure means the internal pressure of the process chamber 201 which is a space where the wafer 200 is placed. Further, the gas supply flow rate: 0 slm means a case where the gas is not supplied. These apply to the following description.

By supplying the seed gas, for example, a chlorosilane-based gas, to the wafer 200 under the aforementioned process conditions, it is possible to adsorb silicon (Si) contained in the seed gas on the surface of the wafer 200 to form a seed (nucleus). Under the aforementioned process conditions, the nucleus formed on the surface of the wafer 200 contains a predetermined amount of chlorine (Cl). Further, under the aforementioned process conditions, the crystal structure of the nucleus formed on the surface of the wafer 200 becomes amorphous.

After the nucleus is formed on the surface of the wafer 200, the valve 243b is closed to stop the supply of the seed gas into the process chamber 201. Then, the interior of the process chamber 201 is vacuum-exhausted to remove a gas and the like remaining in the process chamber 201 from the process chamber 201 (purging). At this time, the valves 243g to 243i are opened to allow an inert gas to be supplied into the process chamber 201.

As the seed gas, it may be possible to use, e.g., a chlorosilane-based gas such as a monochlorosilane (SiH₃Cl, abbreviation: MCS) gas, a dichlorosilane (SiH₂Cl₂, abbreviation: DCS) gas, a trichlorosilane (SiHCl₃, abbreviation: TCS) gas, a tetrachlorosilane (SiCl₄, abbreviation: STC) gas, a hexachlorodisilane (Si₂Cl₆, abbreviation: HCDS) gas, or an octachlorotrisilane (Si₃Cl₈, abbreviation: OCTS) gas. One or more of the various gases exemplified here can be used as the seed gas.

As the seed gas, it may also be possible to use, e.g., a fluorosilane-based gas such as a tetrafluorosilane (SiF₄) gas or a difluorosilane (SiH₂F₂) gas, a bromosilane-based gas such as a tetrabromosilane (SiBr₄) gas or a dibromosilane (SiH₂Br₂) gas, or an iodosilane-based gas such as a tetraiodosilane (SiI₄) gas or a diiodosilane (SiH₂I₂) gas. One or more of the various gases exemplified here can be used as the seed gas.

As the inert gas, it may be possible to use, e.g., a nitrogen (N₂) gas or a rare gas such as an argon (Ar) gas, a helium (He) gas, a neon (Ne) gas, or a xenon (Xe) gas. One or more of the various gases exemplified here can be used as the inert gas. The same applies to each step to be described later.

### [Step S2]

After that, a reducing gas is supplied to the wafer 200 in the process chamber 201, that is, the nucleus formed on the surface of the oxide film.

Specifically, the valve 243d is opened to allow the reducing gas to flow into the gas supply pipe 232d. The flow rate of the reducing gas is adjusted by the MFC 241d, and the reducing gas is supplied into the process chamber 201 via the gas supply pipe 232a and the nozzle 249a and is exhausted through the exhaust port 231a. In this operation, the reducing gas is supplied to the wafer 200 (reducing gas supply). At this time, the valves 243g to 243i may be opened to allow an inert gas to be supplied into the process chamber 201 via the nozzles 249a to 249c, respectively.

An example of the process condition in the reducing gas supply is described as follows.
Reducing gas supply flow rate: 2 to 10 slm
Reducing gas supply time: 2 to 5 minutes
Inert gas supply flow rate (for each gas supply pipe): 0 to 20 slm
Processing pressure: 1,333 to 13,332 Pa
Other process condition is the same as the process conditions in the seed gas supply.

By supplying the reducing gas to the wafer 200 under the aforementioned process conditions, it is possible to desorb Cl from the nucleus formed on the surface of the wafer 200. Cl desorbed from the nucleus produces a gaseous substance containing Cl, which is discharged from the process chamber 201. In the present embodiment, a pressure (processing pressure) in the space where the wafer 200 is placed in the reduction gas supply is made higher than a pressure (processing pressure) in the space where the wafer 200 is placed in the seed gas supply. By doing so, it is possible to promote the desorption of Cl from the nucleus in the reduction gas supply. As a result, it is possible to make the seed layer formed on the wafer 200 low in the Cl concentration.

After Cl is desorbed from the nucleus formed the surface of the wafer 200, the valve 243d is closed to stop the supply of the reducing gas into the process chamber 201. Then, a gas and the like remaining in the process chamber 201 are removed from the process chamber 201 according to the same process procedures and process conditions as the purging in step S1.

As the reducing gas, it may be possible to use, e.g., a hydrogen (H)-containing gas such as a hydrogen (H₂) gas, a deuterium (D₂) gas, or a monosilane gas (SiH₄) gas. The D₂ gas may also be expressed as a ²H₂ gas. One or more of the various gases exemplified here can be used as the reducing gas.

### [Performing Predetermined Number of Times]

By performing a cycle a predetermined number of times (n times, where n is an integer of 1 or more), the cycle including alternately, that is, non-simultaneously without synchronization, performing the above-described steps S1 and S2, as shown in FIG. 4B, it is possible to form a seed layer with the above-mentioned nucleus formed at a high density, that is, a silicon seed layer, on the wafer 200, that is, on the oxide film formed on the surface of the wafer 200. In the present embodiment, by performing steps S1 and S2 alternately, that is, by desorbing Cl from the nucleus formed on the surface of the wafer 200 by supplying the reducing gas each time the seed gas is supplied, it is possible to make the seed layer formed on the wafer 200 low in the Cl concentration. Under the aforementioned process conditions, it is possible to make the crystal structure of the seed layer formed on the wafer 200 amorphous.

After the formation of the amorphous seed layer on the wafer 200 is completed, the output of the heater 207 is adjusted to change the internal temperature of the process chamber 201, that is, the temperature of the wafer 200, to a temperature higher than the temperature of the wafer 200 in the seed layer formation. Until the temperature of the wafer 200 reaches a desired temperature and stabilizes, the valves 243g to 243i are opened to allow an inert gas to be supplied into the process chamber 201 via the nozzles 249a to 249c, respectively, and the inert gas is exhausted through the exhaust port 231a to purge the interior of the process chamber 201.

### [First Film Formation]

After the seed layer formation is completed, first film formation is performed. In this step, a precursor gas is supplied as a first process gas to the wafer 200 in the process chamber 201, that is, the surface of the amorphous seed layer formed on the wafer 200.

Specifically, the valve 243a is opened to allow the precursor gas to flow into the gas supply pipe 232a. The flow rate of the precursor gas is adjusted by the MFC 241a, and the precursor gas is supplied into the process chamber 201 via the nozzle 249a and is exhausted through the exhaust port 231a. In this operation, the precursor gas is supplied to the wafer 200 (precursor gas supply). At this time, the valves 243g to 243i may be opened to allow an inert gas to be supplied into the process chamber 201 via the nozzles 249a to 249c, respectively.

The process conditions in the first film formation are exemplified as follows.
Precursor gas supply flow rate: 0.01 to 5 slm
Precursor gas supply time: 1 to 300 minutes
Inert gas supply flow rate (for each gas supply pipe): 0 to 20 slm
Processing temperature: 450 to 550 degrees C.
Processing pressure: 30 to 400 Pa

By supplying the precursor gas, for example, a silane-based gas, to the wafer 200 under the aforementioned process conditions, the precursor gas can be decomposed in the gas phase to adsorb (deposit) Si on the surface of the wafer 200, that is, on the seed layer formed on the wafer 200. As a result, as shown in FIG. 4C, it is possible to form a first silicon film as a first film on the wafer 200, that is, on the seed layer formed on the wafer 200. When a silane-based gas containing no Cl is used as the precursor gas, the first film formed on the wafer 200 becomes a film containing no Cl. Further, under the aforementioned process conditions, the crystal structure of the first film formed on the wafer 200 becomes amorphous. Further, the crystal structure of the seed layer formed on the wafer 200 is also maintained as amorphous.

After the amorphous first film formation on the wafer 200 is completed, the valve 243a is closed to stop the supply of the precursor gas into the process chamber 201. Then, a gas and the like remaining in the process chamber 201 are removed from the process chamber 201 (purging) according to the same process procedures and process conditions as the purging in the seed layer formation.

As the precursor gas, it may be possible to use, e.g., a silicon hydride gas such as a monosilane (SiH₄) gas, a disilane (Si₂H₆) gas, a trisilane (Si₃H₈) gas, a tetrasilane (Si₄H₁₀) gas, a pentasilane (Si₅H₁₂) gas, or a hexasilane (Si₆H₁₄) gas. One or more of the various gases exemplified here can be used as the precursor gas. In order to ensure that the crystal state of the first film at the end of the first film formation is amorphous, a low-order silicon hydride gas such as the monosilane gas may be used as the precursor gas.

### (Step B)

After step A is completed, second film formation is performed as step B. In this step, a precursor gas and a dopant gas are supplied as a second process gas to the wafer 200 in the process chamber 201, that is, the surface of the first film formed on the wafer 200.

Specifically, the valves 243a and 243c are opened to allow the precursor gas and the dopant gas to flow into the gas supply pipes 232a and 232c, respectively. The flow rates of the precursor gas and the dopant gas are adjusted by the MFCs 241a and 241c, and the precursor gas and the dopant gas are supplied into the process chamber 201 via the nozzles 249a and 249c and are exhausted through the exhaust port 231a. In this operation, the precursor gas and the dopant gas are supplied to the wafer 200 (precursor gas supply+dopant gas supply). At this time, the valves 243g to 243i may be opened to allow an inert gas to be supplied into the process chamber 201 via the nozzles 249a to 249c, respectively.

An example of the process condition in the second film formation is described as follows.
Precursor gas supply flow rate: 0.01 to 5 slm
Dopant gas supply flow rate: 0.01 to 5 slm
Each gas supply time: 1 to 300 minutes
Processing temperature: 450 to 550 degrees C.
Processing pressure: 30 to 400 Pa
Other process conditions are the same as the process conditions in the first film formation.

By supplying the precursor gas, for example, a silane-based gas, and the dopant gas, for example, a phosphorus (P)-containing gas, to the wafer 200 under the aforementioned process conditions, the precursor gas and the dopant gas can be decomposed in the gas phase to adsorb (deposit) Si on the surface of the wafer 200, that is, on the amorphous first film formed on the wafer 200. As a result, as shown in FIG. 4D, it is possible to form a second silicon film doped with P as a dopant, as a second film on the wafer 200, that is, on the first film formed on the wafer 200. When a silane-based gas containing no Cl is used as the precursor gas, the second film formed on the wafer 200 becomes a film containing no Cl. Further, under the aforementioned process conditions, the crystal structure of the second film formed on the wafer 200 becomes amorphous. Further, the crystal structures of the seed layer and the first film formed on the wafer 200 are also maintained as amorphous.

After the amorphous second film formation on the wafer 200 is completed, the valves 243a and 243c are closed to stop the supply of the precursor gas and the dopant gas into the process chamber 201, respectively. Then, a gas and the like remaining in the process chamber 201 are removed from the process chamber 201 according to the same process procedures and process conditions as the purging in the seed layer formation.

One or more of the various silicon hydride gases exemplified in the first film formation can be used as the precursor gas. Further, in order to ensure that the crystal state of the second film at the end of the second film formation is amorphous, a low-order silicon hydride gas such as the monosilane gas may be used as the precursor gas.

As the dopant gas, in addition to the phosphorus (P)-containing gas such as a phosphine (PH₃) gas, it may be possible to use, e.g., a boron (B)-containing gas such as a diborane (B₂H₆) gas, or an arsenic (As)-containing gas such as an arsine (AsH₃) gas. One or more of these can be used as the dopant gas.

### (Step C)

After step B is completed, crystallization is performed as step C.

Specifically, the output of the heater 207 is adjusted to change the internal temperature of the process chamber 201, that is, the temperature of the wafer 200, to a temperature higher than the temperature of the wafer 200 in the above-described second film formation, and the seed layer, the first film, and the second film are heat-treated (annealed). At this time, the valves 243g to 243i may be opened to allow an inert gas to be supplied into the process chamber 201 via the nozzles 249a to 249c, respectively.

The process conditions in the crystallization are exemplified as follows.
Inert gas supply flow rate (for each gas supply pipe): 0 to 20 slm
Processing time: 60 to 600 minutes
Processing temperature: 550 to 650 degrees C.
Processing pressure: 1 to 101,325 Pa

By performing the annealing under the aforementioned process conditions, as shown in FIG. 4E, each of the seed layer, the first film, and the second film can be polymerized (crystallized, that is, polycrystallized). As described above, the first film is an amorphous film not doped with a dopant, and the second film is an amorphous film doped with a dopant. As a result, in this step, the crystallization of the second film can be started earlier than the crystallization of the first film. Further, in this step, the crystallization of the second film can be completed earlier than the crystallization of the first film. As a result, in this step, the first film can be crystallized starting from the crystal grains of the second film. That is, the crystalline state of the second film can be taken over by the first film.

Further, the crystal grain size of the amorphous film doped with the dopant can be made larger than that of the amorphous film not doped with the dopant. In this step, since the crystallization of the second film is started earlier than the crystallization of the first film and is completed earlier than the crystallization of the first film, the grain size of the second film crystallized earlier can be made larger, and the larger grain size of the second film can be taken over by the first film crystallized later. As a result, when the first film is crystallized, it is possible to increase the grain size of the first film.

As described above, since the first film takes over the crystalline state of the second film, it is effective to further increase the grain size of the second film in order to further increase the grain size of the first film. Here, by setting the thickness of the amorphous second film to be equal to or thicker than the thickness of the amorphous first film, the grain size of the crystallized second film can be further increased, and as a result, it is possible to further increase the grain size of the first film. Further, by making the thickness of the amorphous second film larger than the thickness of the amorphous first film, the grain size of the crystallized second film can be further increased, and as a result, it is possible to further increase the grain size of the first film.

Further, by performing the annealing under the aforementioned process conditions, some of dopants in the second film may diffuse into the first film. As a result, the dopant may be added at a predetermined concentration in a region of the first film, for example, near an interface with the second film.

### (Step E)

After step C is completed, modification is performed as step E. In this step, a modifying gas is supplied to the wafer 200 in the process chamber 201, that is, the surface of the crystallized second film.

Specifically, the valve 243f is opened to allow the modifying gas to flow into the gas supply pipe 232f The flow rate of the modifying gas is adjusted by the MFC 241f, and the modifying gas is supplied into the process chamber 201 via the gas supply pipe 232c and the nozzle 249c and is exhausted through the exhaust port 231a. In this operation, the modifying gas is supplied to the wafer 200 (modifying gas supply). At this time, the valves 243g to 243i may be opened to allow an inert gas to be supplied into the process chamber 201 via the nozzles 249a to 249c, respectively.

An example of the process condition in the modification is described as follows.
Modifying gas supply flow rate: 1 to 10 slm
Modifying gas supply time: 1 to 5 minutes
Inert gas supply flow rate (for each gas supply pipe): 0 to 20 slm
Processing temperature: 500 to 800 degrees C.
Processing pressure: 1 to 101,325 Pa

By supplying the modifying gas, for example, an O-containing gas (oxidizing gas), to the wafer 200 under the aforementioned process conditions, a portion of the first film and the second film in which the dopant is present can be oxidized. As a result, as shown in FIG. 4F, it is possible to modify the portion of the first film and the second film in which the dopant is present into an oxide film which is easily etched in etching to be described later (a silicon oxide film if a silicon film is formed as the first film and the second film).

After the modification of the portion of the first film and the second film in which the dopant is present is completed, the valve 243f is closed to stop the supply of the modifying gas into the process chamber 201. Then, a gas and the like remaining in the process chamber 201 are removed from the process chamber 201 according to the same process procedures and process conditions as the purging in the seed layer formation.

As the modifying gas, it may be possible to use, e.g., an O-containing gas such as an oxygen (O₂) gas, an ozone (O₃) gas, water vapor (H₂O gas), a hydrogen peroxide (H₂O₂) gas, a nitric oxide (NO) gas, a nitrous oxide (N₂O) gas, a nitrogen dioxide (NO₂) gas, a carbon monoxide (CO) gas, or a carbon dioxide (CO₂) gas. In addition to these gases, an O-containing gas+H-containing gas can also be used as the modifying gas. In addition to a H₂ gas, a ²H₂ gas may be used as the H-containing gas. For example, an O₂ gas+H₂ gas, an O₃ gas)+H₂ gas, or the like can be used as the modifying gas. Further, a gas obtained by exciting at least one selected from the group of these gases to a plasma state can also be used as the modifying gas. One or more of the various gases exemplified here can be used as the modifying gas.

In addition, in the present disclosure, the description of two gases such as “O-containing gas+H-containing gas” together means a mixture of O-containing gas and H-containing gas. When the mixture is supplied, the two gases may be mixed (pre-mixed) in a supply pipe and then supplied into the process chamber 201, or the two gases may be supplied separately from different supply pipes into the process chamber 201 and then mixed (post-mixed) in the process chamber 201.

### (Step D)

After step E is completed, etching is performed as step D. In this step, the surface of the wafer 200 in the process chamber 201, that is, the portion of the first film and the second film where the dopant is present or the surface of the modified oxide film is exposed to an etching agent.

Specifically, the valve 243e is opened to allow the etching agent to flow into the gas supply pipe 232e. The flow rate of the etching agent is adjusted by the MFC 241e, and the etching agent is supplied into the process chamber 201 via the gas supply pipe 232b and the nozzle 249b and is exhausted through the exhaust port 231a. In this operation, the surface of the wafer 200 is exposed to the etching agent (etching agent exposure). At this time, the valves 243g to 243i may be opened to allow an inert gas to be supplied into the process chamber 201 via the nozzles 249a to 249c, respectively.

An example of the process condition in the etching is described as follows.
Etching agent supply flow rate: 1 to 10 slm
Etching agent supply time: 1 to 10 minutes
Inert gas supply flow rate (for each gas supply pipe): 0 to 20 slm
Processing temperature: room temperature (25 degrees C.) to 1,000 degrees C.
Processing pressure: 133 to 50,000 Pa

By supplying the etching agent to the wafer 200 under the aforementioned process conditions, a portion, which is modified into the oxide film, of the crystallized first film and second film, that is, the portion where the dopant is present, can be etched (removed). As a result, as shown in FIG. 4G, it is possible to expose a surface of the first film which contains no dopant. The first film obtained after the etching is a non-doped film not doped with a dopant.

As described above, in the crystallization, some of the dopants in the second film may diffuse into the first film. In that case, in the etching, at least the second film is removed, and at the same time, a portion of the first film into which the dopants in the second film diffuse is also removed. That is, the film thickness of the first film after performing the etching may be thinner by a depth of diffusion of the dopants from the second film into the first film at least in the crystallization than the film thickness of the first film immediately after forming the first film. Therefore, in this case, in order to set the film thickness of the first film obtained after performing the etching, that is, the film thickness of the first film finally obtained, to a desired thickness, in the first film formation, it is desirable to form the first film thicker by the depth or more of diffusion of the dopants from the second film into the first film in the crystallization than the film thickness of the first film obtained after performing the etching. For example, in the first film formation, it is desirable to form the first film thicker by the depth of diffusion of the dopants from the second film into the first film in the crystallization than the film thickness of the first film obtained after performing the etching.

After removing the portion, which is modified into the oxide film, of the first film and second film, that is, the portion where the dopant is present, the valve 243e is closed to stop the supply of the etching agent into the process chamber 201. Then, a gas and the like remaining in the process chamber 201 are removed from the process chamber 201 by the same process procedures and process conditions as in the purging in the seed layer formation.

As the etching agent, it may be possible to use, e.g., etching gases such as a hydrogen fluoride (HF) gas, a chlorine trifluoride (ClF₃) gas, a chlorine fluoride gas (ClF) gas, a fluorine (F₂) gas, a nitrogen trifluoride (NF₃) gas, a nitrosyl fluoride (FNO) gas, a hydrogen chloride (HCl) gas, and a chlorine (Cl₂) gas, or a mixture thereof. One or more of the various gases exemplified here can be used as the etching agent. When modifying the portion of the first film and the second film in which the dopant is present into the oxide film, a fluorine-based gas (fluorine-containing gas) such as the HF gas may be used as the etching agent. When the fluorine-based gas such as the HF gas is used, only an oxidized film thickness of the crystallized silicon film, that is, the polycrystalline silicon film, can be selectively etched, so that a non-oxidized film thickness can be left without being etched. That is, when the fluorine-based gas such as the HF gas is used, it is possible to obtain a polycrystalline silicon film having a predetermined film thickness by etching only the oxidized film thickness of the polycrystalline silicon film.

### (After-Purging and Returning to Atmospheric Pressure)

After the etching is completed, an inert gas acting as a purge gas is supplied into the process chamber 201 from each of the nozzles 249a to 249c and is exhausted through the exhaust port 231a. Thus, the interior of the process chamber 201 is purged to remove a gas and reaction by-products remaining in the process chamber 201 from the process chamber 201 (after-purging). After that, the internal atmosphere of the process chamber 201 is substituted with an inert gas (inert gas substitution) and the internal pressure of the process chamber 201 is returned to the atmospheric pressure (returning to atmospheric pressure).

### (Boat Unloading and Wafer Discharging)

After that, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat unloading, the shutter 219s is moved and the lower end opening of the manifold 209 is sealed by the shutter 219s via the O-ring 220c (shutter closed). The processed wafers 200 are unloaded from the reaction tube 203 and are discharged from the boat 217 (wafer discharging).

### (3) Effects of the Present Embodiment

According to the present embodiment, one or more effects set forth below may be achieved.

(a) By performing the first film formation, the second film formation, the crystallization, and the etching in order, it is possible to increase the grain size of the finally obtained first film, thereby reducing the density of crystal grain boundaries in the finally obtained first film. As a result, it is possible to increase the mobility of electrons in the finally obtained first film.

(b) By using the first film as an amorphous film not doped with the dopant and using the second film as an amorphous film doped with the dopant, in the crystallization, it is possible to start the crystallization of the second film earlier than the crystallization of the first film. As a result, it is possible to increase the grain size of the second film crystallized earlier and take over (succeed to) the grain size thereof by the first film crystallized later. That is, it is possible to increase the grain size of the first film obtained by the crystallization.

(c) When some of the dopants in the second film diffuse into the first film in the crystallization, the portion of the first film into which the dopants in the second film diffuse can be also removed in the etching, so that the portion of the first film not doped with the dopant can be left. This makes it possible to expose the portion of the first film not doped with the dopant, that is, the portion of the first film which contains no dopant. As a result, it is possible to make the first film obtained after the etching a non-doped film not doped with the dopant.

(d) After performing the crystallization, by performing the modification before performing the etching, it is possible to easily remove (easily etch by the etching agent) the portion of the first film and the second film in which the dopant is present after the crystallization, by the etching. This makes it possible to selectively etch the portion of the first film and the second film in which the dopant is present, in the etching.

(e) In the crystallization, by setting the temperature of the wafer 200 to 550 degrees or higher and 650 degrees or lower, since the second film can be appropriately crystallized earlier than the first film, it is possible to suppress some of the dopants in the second film from diffusing into the first film.

(f) In the first film formation, by forming the first film thicker by the depth or more, for example, by the depth, of diffusion of the dopants from the second film into the first film in the crystallization than the film thickness of the first film obtained after performing the etching, it is possible to prevent the film thickness of the first film, which is obtained after performing the etching, from being thinner than a desired film thickness.

(g) In the second film formation, by setting the thickness of the second film to the thickness or thicker of the first film, for example, to be thicker than the thickness of the first film, the grain size of the second film may be increased in the crystallization, and the grain size thereof can be taken over by the first film, which makes it possible to further increase the grain size of the first film.

(h) The method of the present embodiment is particularly effective when an oxide film is formed on the surface of the wafer 200 before film formation. When a film is formed on the oxide film, the grain size of this film may be small, but according to this method, even when the film is formed on the oxide film, the grain size of this film can be increased. That is, according to this method, it is possible to form a film having an enlarged grain size on the oxide film.

(i) The above-described effects can be similarly obtained even when the above-mentioned various seed gases are used, when the above-mentioned various reducing gases are used, when the above-mentioned various precursor gases are used, when the above-mentioned various modifying gases are used, when the above-mentioned various etching agents are used, and when the above-mentioned various inert gases are used.

### (4) Modifications

In the above-described embodiment, the example in which the portion of the crystallized first film and second film where the dopant is present is modified and then removed by dry etching has been described, but the present disclosure is not limited thereto.

For example, the portion of the crystallized first film and second film where the dopant is present may be modified and then removed by wet etching. In this case, by using, for example, an aqueous HF solution instead of the etching gas, as the etching agent, to expose the surface of the wafer 200 to the aqueous HF solution, the same etching as described above can be performed. Also in this case, the same effects as the above-described embodiment can be obtained.

Further, for example, in the above-described embodiment, as shown in FIGS. 4A to 4G, the example in which the portion of the crystallized first film and second film where the dopant is present is modified and then etched has been described, but the present disclosure is not limited thereto.

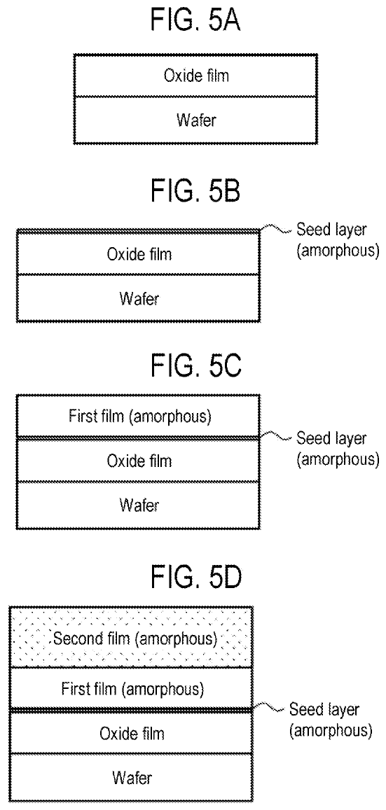

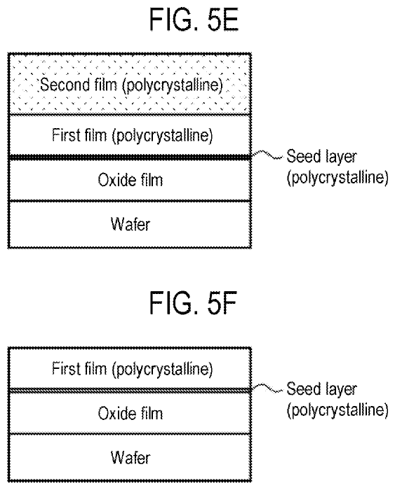

For example, as shown in the following processing sequence and FIGS. 5A to 5F, the portion of the crystallized first film and second film where the dopant is present may be etched without being modified. That is, the modification may be omitted. In this case, a chlorine-based gas (chlorine-containing gas) such as a HCl gas or a Cl₂ gas may be used as the etching agent.

Seed layer formation→First film formation→Second film formation→Crystallization→Etching

Even in this case, the same effects as the above-described embodiment can be obtained.

Further, in the above-described embodiment, the example in which the silicon film is formed as the first film and the second film on the wafer 200 has been described, but the present embodiment is not limited thereto. For example, the method of the present embodiment can be also applied even when a germanium film (Ge film) or a silicon germanium film (SiGe film) is formed as the first film and the second film on the wafer 200. Even in these cases, the same effects as the above-described embodiment can be obtained.

### Second Embodiment of the Present Disclosure

In the above-described first embodiment, the example in which the second film having a lower crystallization temperature than the first film, that is, the second film doped with the dopant, is formed on the first film in step B (the second film formation) has been described. However, in step B, a second film not doped with a dopant may be formed as the second film.

A processing sequence according to the second embodiment includes:
(a) step A of forming a first film in an amorphous state on a wafer 200 by supplying a first process gas to the wafer 200;
(b) step B of forming a second film in an amorphous state on the first film by supplying a second process gas to the wafer 200;
(c) step C of crystallizing the first film and the second film formed on the wafer 200 by heating the first film and the second film; and
(d) step D of removing at least the second film by exposing the surface of the wafer 200 to an etching agent after crystallizing the first film and the second film.

In the second embodiment, the first film is a film not doped with a dopant, and the second film is a film not doped with a dopant. That is, in the second embodiment, both the first film and the second film are films not doped with a dopant.

Also in the second embodiment, as in the first embodiment, in step A, a silicon seed layer may be formed as a seed layer before the first film is formed. In this case, the seed layer is formed on the surface of the wafer 200, and the first film is formed on the seed layer.

In step A, when a first silicon film not doped with a dopant is formed as the first film, a precursor gas such as a silane-based gas can be used as the first process gas.

In step B, when a second silicon film not doped with a dopant is formed as the second film, a precursor gas such as a silane-based gas can be used as the second process gas.

The processing sequence according to the second embodiment may further include: (e) step E of modifying the second film after performing step C and before performing step D. In this case, in step E, the second film may be oxidized. This makes it possible to easily remove (easily etch by the etching agent) in step D the second film after performing step C.

The second embodiment is the same as in the first embodiment except that the second film formed in step B does not contain a dopant (only that the dopant gas is not supplied in step B). The process procedures and process conditions in each step of the processing sequence of the second embodiment can be the same as the process procedures and process conditions in each step of the above-described processing sequence of the first embodiment.

The second embodiment can also obtain the same effects as in the first embodiment.

Also in the second embodiment, the crystallized and modified second film can be removed by either dry etching or wet etching. In any case, the same effects as the above-described embodiment can be obtained.

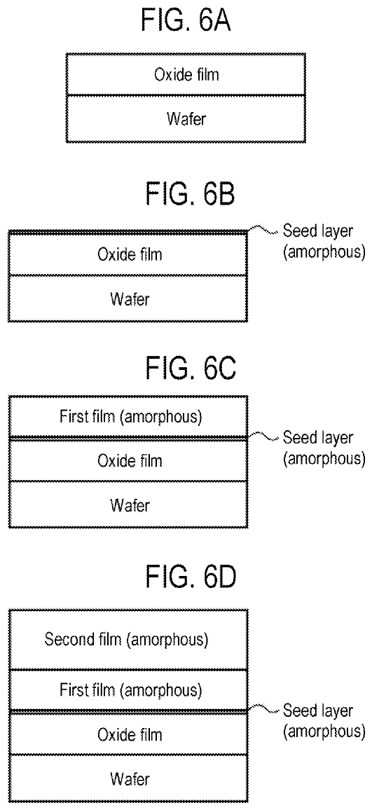

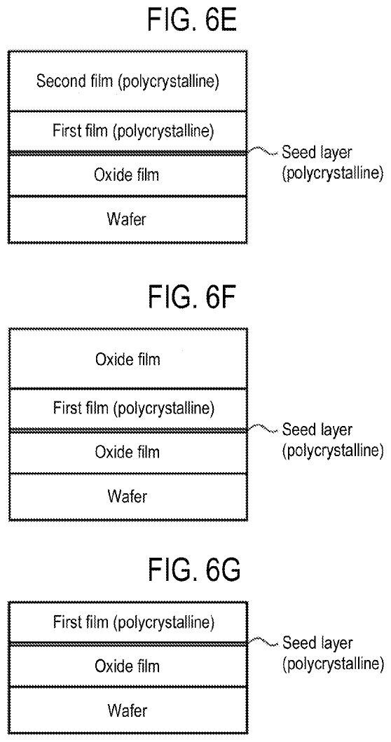

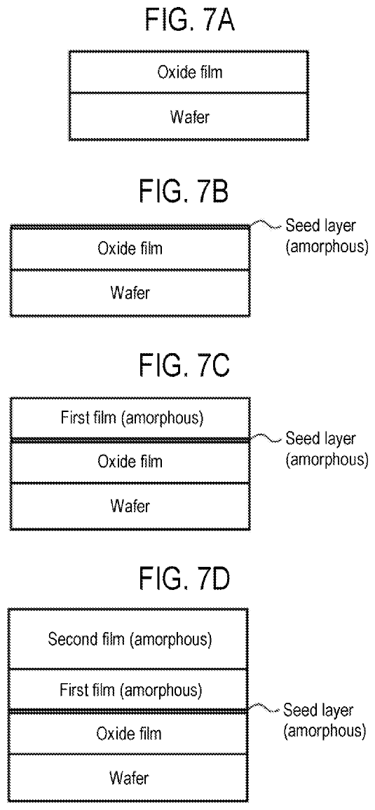

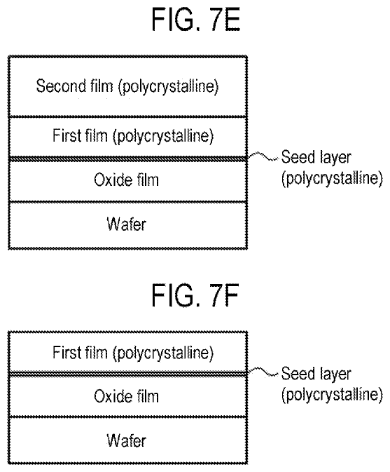

Further, also in the second embodiment, as in the first embodiment, as shown in FIGS. 6A to 6G, the crystallized and modified second film can be etched. Further, as shown in FIGS. 7A to 7F, the crystallized second film can be etched without being modified. That is, the second film may or not be modified after performing the crystallization and before performing the etching. In either case, the same etching agent as in the first embodiment may be used. That is, when etching the second film crystallized and modified into the oxide film, a fluorine-based gas (fluorine-containing gas) such as a HF gas or an aqueous HF solution may be used as the etching agent. When etching the crystallized second film without being modified, a chlorine-based gas (chlorine-containing gas) such as a HCl gas or a Cl₂ gas may be used as the etching agent. In either case, the same effects as the above-described embodiment can be obtained.

### Other Embodiments of the Present Disclosure

The various embodiments of the present disclosure has been specifically described above. However, the present disclosure is not limited to the above-described embodiments, but various modifications can be made without departing from the gist thereof.

In the above-described embodiments, an example in which a series of steps from the seed layer formation to the etching is performed in the same process chamber 201 (in-situ) has been described. However, the present disclosure is not limited to these embodiments. Of the series of steps, the seed layer formation to some steps may be performed in the same process chamber, and the subsequent steps may be performed in another process chamber (ex-situ).

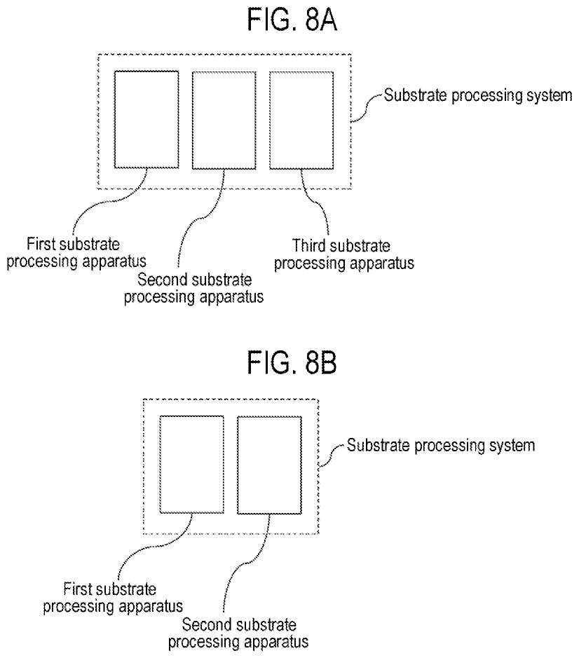

For example, the seed layer formation, the first film formation, and the second film formation, the crystallization, and the etching may be performed by using different stand-alone type apparatuses (first substrate processing apparatus, second substrate processing apparatus, and third substrate processing apparatus, respectively). In this case, as shown in FIG. 8A, a substrate processing system can be configured by the first substrate processing apparatus, the second substrate processing apparatus, and the third substrate processing apparatus.

Further, for example, a series of steps from the seed layer formation, the first film formation, the second film formation, to the crystallization, and the etching may be performed by using different stand-alone type apparatuses (first substrate processing apparatus and second substrate processing apparatus, respectively). In this case, as shown in FIG. 8B, a substrate processing system can be configured by the first substrate processing apparatus and the second substrate processing apparatus.

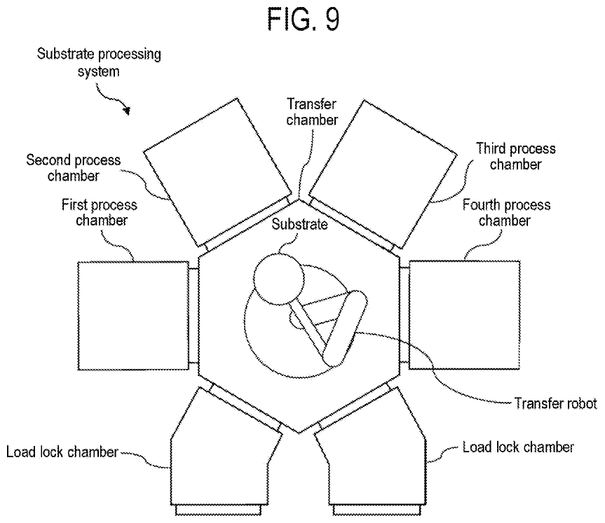

Further, for example, the seed layer formation, the first film formation, and the second film formation, the crystallization, and the etching may be performed in different process chambers (first process chamber, second process chamber, and third process chamber) in a cluster apparatus, respectively. In this case, as shown in FIG. 9, a substrate processing system can be configured by the cluster apparatus having the first process chamber, the second process chamber, and the third process chamber. A fourth process chamber in FIG. 9 can be used as a process chamber for performing other process.

Further, for example, a series of steps from the seed layer formation, the first film formation, the second film formation, to the crystallization, and the etching may be performed in different process chambers (first process chamber and second process chamber) in a cluster apparatus, respectively. In this case, as shown in FIG. 9, a substrate processing system can be configured by the cluster apparatus having the first process chamber and the second process chamber. The third process chamber and the fourth process chamber in FIG. 9 may be used as process chambers for performing other processes, and a series of steps from the first film formation, the second film formation, to the crystallization, and the etching may be performed in the third process chamber and the fourth process chamber, respectively.

Also in these cases, the same effects as in the above-described embodiments can be obtained. In the above-described various cases, if the series of steps are performed in-situ, the wafer 200 is not exposed to the atmosphere on the way, so that the wafer 200 can be consistently processed while being placed under vacuum, which can lead to stable substrate processing. Further, if some steps are performed by ex-situ, the internal temperature of each process chamber can be set in advance to, for example, the processing temperature at each step or a temperature close to the processing temperature, thereby shortening the time taken for temperature adjustment, which can lead to the increase of production efficiency.

Recipes used for substrate processing may be prepared individually according to the processing contents and may be stored in the memory 121c via a telecommunication line or the external memory 123. Moreover, at the beginning of each process, the CPU 121a may properly select an appropriate recipe from the recipes stored in the memory 121c according to the substrate processing contents. Thus, it is possible for a single substrate processing apparatus to form films of various kinds, composition ratios, qualities, and thicknesses with enhanced reproducibility. Further, it is possible to reduce an operator's burden and to quickly start each process while avoiding an operation error.

The recipes mentioned above are not limited to newly-prepared ones but may be prepared, for example, by modifying existing recipes that are already installed in the substrate processing apparatus. Once the recipes are modified, the modified recipes may be installed in the substrate processing apparatus via a telecommunication line or a recording medium storing the recipes. In addition, the existing recipes already installed in the existing substrate processing apparatus may be directly modified by operating the input/output device 122 of the substrate processing apparatus.

In the above-described embodiments, an example in which a film is formed using a batch-type substrate processing apparatus capable of processing a plurality of substrates at a time has been described. The present disclosure is not limited to the above-described embodiments, but may be suitably applied, for example, to a case where a film is formed using a single-wafer type substrate processing apparatus capable of processing a single substrate or several substrates at a time. In addition, in the above-described embodiments, an example in which a film is formed using a substrate processing apparatus provided with a hot-wall-type process furnace has been described. The present disclosure is not limited to the above-described embodiments, but may be suitably applied to a case where a film is formed using a substrate processing apparatus provided with a cold-wall-type process furnace.

Even in the case of using these substrate processing apparatuses, a film can be formed according to the same process procedures and process conditions as in the above-described embodiments and modifications, and the same effects as the above-described embodiments and modifications are achieved.

The above-described embodiments and modifications may be used in proper combination. The process procedures and process conditions used in this case may be the same as, for example, the process procedures and process conditions in the above-described embodiments.

### Examples

As Example 1, using the substrate processing apparatus shown in FIG. 1, a silicon film was formed on a wafer with a silicon oxidation film formed on the surface of the wafer, according to the processing sequence (the seed layer formation, the first film formation, the second film formation, the crystallization, the modification, and the etching) of the first embodiment, to prepare an evaluation sample. The process conditions in each step were set to predetermined conditions within the process condition range in each step of the processing sequence of the first embodiment. The thickness of an amorphous silicon film (non-doped) as a first film was set to 30 nm, the thickness of an amorphous silicon film (P-doped) as a second film was set to 15 nm, and the thickness of a silicon film (non-doped) finally formed on the wafer by performing the etching was set to 30 nm.

As Comparative Example 1, using the substrate processing apparatus shown in FIG. 1, a silicon film was formed on a wafer with a silicon oxidation film formed on the surface of the wafer, by performing the seed layer formation, the first film formation, and the crystallization in the processing sequence of the first embodiment, to prepare an evaluation sample. The process conditions in each step were the same as the process conditions in each step of Example 1. The thickness of a silicon film (non-doped) finally formed on the wafer by performing the crystallization was set to 30 nm.

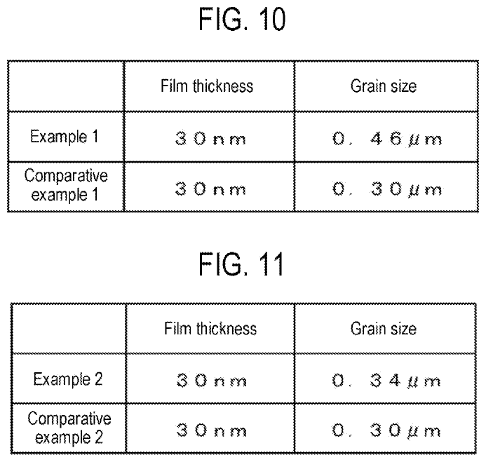

Then, the grain size of the silicon film in each of the evaluation samples of Example 1 and Comparative Example 1 was measured. The results are shown in FIG. 10. As shown in FIG. 10, it is confirmed that Example 1 is able to increase the grain size of the silicon film over Comparative Example 1.

As Example 2, using the substrate processing apparatus shown in FIG. 1, a silicon film was formed on a wafer with a silicon oxidation film formed on the surface of the wafer, according to the processing sequence (the seed layer formation, the first film formation, the second film formation, the crystallization, the modification, and the etching) of the second embodiment, to prepare an evaluation sample. The process conditions in each step were set to predetermined conditions within the process condition range in each step of the processing sequence of the second embodiment. The thickness of an amorphous silicon film (non-doped) as a first film was set to 30 nm, the thickness of an amorphous silicon film (non-doped) as a second film was set to 15 nm, and the thickness of a silicon film (non-doped) finally formed on the wafer by performing the etching was set to 30 nm.

As Comparative Example 2, using the substrate processing apparatus shown in FIG. 1, a silicon film was formed on a wafer with a silicon oxidation film formed on the surface of the wafer, by performing the seed layer formation, the first film formation, and the crystallization in the processing sequence of the second embodiment, to prepare an evaluation sample. The process conditions in each step were the same as the process conditions in each step of Example 2. The thickness of a silicon film (non-doped) finally formed on the wafer by performing the crystallization was set to 30 nm.

Then, the grain size of the silicon film in each of the evaluation samples of Example 2 and Comparative Example 2 was measured. The results are shown in FIG. 11. As shown in FIG. 11, it is confirmed that Example 2 is able to increase the grain size of the silicon film over Comparative Example 2.

Comparing Example 1 and Example 2, it is confirmed that Example 1, that is, the processing sequence of the first embodiment, is able to increase the grain size of the silicon film over Example 2, that is, the processing sequence of the second embodiment.

While the various embodiments of the present disclosure have been specifically described above, the present disclosure also includes the following aspects.

### (Supplementary Note 1)

According to one aspect of the present disclosure, there is provided a method of manufacturing a semiconductor device or a method of processing a substrate, including:
(a) a step of forming a first film in an amorphous state on a substrate by supplying a first process gas to the substrate;
(b) a step of forming a second film in an amorphous state on the first film by supplying a second process gas to the substrate;
(c) a step of crystallizing the first film and the second film formed on the substrate by heating the first film and the second film; and
(d) a step of removing at least the second film by exposing the surface of the substrate to an etching agent after crystallizing the first film and the second film.

### (Supplementary Note 2)

The method of Supplementary Note 1, further includes:
(e) a step of modifying the second film after performing (c) and before performing (d).

### (Supplementary Note 3)

The method of Supplementary Note 1 or 2, further includes:
(e) a step of oxidizing the second film after performing (c) and before performing (d).

### (Supplementary Note 4)

According to another aspect of the present disclosure, there is provided a substrate processing system including:
a first process gas supply system configured to supply a first process gas to a substrate;
a second process gas supply system configured to supply a second process gas to the substrate;
a heater configured to heat the substrate;
an etching agent exposure system configured to expose the substrate to an etching agent; and
a controller configured to be capable of controlling the first process gas supply system, the second process gas supply system, the heater, and the etching agent exposure system so as to perform each process (each step) of Supplementary Note 1.

### (Supplementary Note 5)

According to another aspect of the present disclosure, there is provided a program that causes, by a computer, a substrate processing system to perform each process (each step) of Supplementary Note 1, or a non-transitory computer-readable recording medium storing the program.

According to the present disclosure in some embodiments, it is possible to form a high quality film on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
(a) forming a first film in an amorphous state on the substrate by supplying a first process gas to the substrate;
(b) forming a second film in an amorphous state, which has a crystallization temperature lower than a crystallization temperature of the first film, on the first film by supplying a second process gas to the substrate;
(c) crystallizing the first film and the second film formed on the substrate by heating the first film and the second film; and
(d) removing at least the second film by exposing a surface of the substrate to an etching agent after crystallizing the first film and the second film.

2. The method of claim 1, wherein the first film is a film not doped with a dopant, and wherein the second film is a film doped with a dopant.

3. The method of claim 2, wherein in (c), a part of the dopant in the second film is diffused into the first film, and
wherein in (d), a portion of the first film into which the dopant in the second film is diffused is also removed.

4. The method of claim 3, wherein in (d), a surface of the first film, which does not contain the dopant, is exposed.

5. The method of claim 2, further comprising: (e) modifying at least one portion, where the dopant is present, in at least one selected from the group of the first film and the second film after performing (c) and before performing (d).

6. The method of claim 2, further comprising: (e) oxidizing at least one portion, where the dopant is present, in at least one selected from the group of the first film and the second film after performing (c) and before performing (d).

7. The method of claim 1, wherein in (c), the crystallization of the second film is started earlier than the crystallization of the first film.

8. The method of claim 1, wherein in (c), the crystallization of the second film is completed earlier than the crystallization of the first film.

9. The method of claim 7, wherein in (c), the first film is crystallized starting from crystal grains of the second film.

10. The method of claim 7, wherein in (c), a crystal state of the second film is taken over by the first film.

11. The method of claim 1, wherein in (c), a temperature of the substrate is set to 550 degrees C. or higher and 650 degrees C. or lower.

12. The method of claim 3, wherein in (a), the first film is formed thicker by a depth or more of diffusion of the dopant from the second film into the first film in (c) than a film thickness of the first film obtained after performing (d).

13. The method of claim 3, wherein in (a), the first film is formed thicker by a depth of diffusion of the dopant from the second film into the first film in (c) than a film thickness of the first film obtained after performing (d).

14. The method of claim 2, wherein a thickness of the second film is made equal to or thicker than a thickness of the first film.

15. The method of claim 2, wherein a thickness of the second film is made thicker than a thickness of the first film.

16. The method of claim 1, wherein the first film is an amorphous silicon film not doped with a dopant, and
wherein the second film is an amorphous silicon film doped with a dopant.

17. The method of claim 1, wherein an oxide film is formed on the surface of the substrate, and
wherein in (a), the first film is formed on the oxide film.

18. A method of manufacturing a semiconductor device comprising the method of claim 1.

19. A substrate processing system comprising:
a first process gas supply system configured to supply a first process gas to a substrate;
a second process gas supply system configured to supply a second process gas to the substrate;
a heater configured to heat the substrate;
an etching agent exposure system configured to expose the substrate to an etching agent; and
a controller configured to be capable of controlling the first process gas supply system, the second process gas supply system, the heater, and the etching agent exposure system so as to perform a process including:
(a) forming a first film in an amorphous state on the substrate by supplying the first process gas to the substrate;
(b) forming a second film in an amorphous state, which has a crystallization temperature lower than a crystallization temperature of the first film, on the first film by supplying the second process gas to the substrate;
(c) crystallizing the first film and the second film formed on the substrate by heating the first film and the second film; and
(d) removing at least the second film by exposing a surface of the substrate to the etching agent after crystallizing the first film and the second film.

20. A non-transitory computer-readable recording medium storing a program that causes, by a computer, a substrate processing system to perform a process comprising:
(a) forming a first film in an amorphous state on a substrate by supplying a first process gas to the substrate;
(b) forming a second film in an amorphous state, which has a crystallization temperature lower than a crystallization temperature of the first film, on the first film by supplying a second process gas to the substrate;
(c) crystallizing the first film and the second film formed on the substrate by heating the first film and the second film; and
(d) removing at least the second film by exposing a surface of the substrate to an etching agent after crystallizing the first film and the second film.
